(19) United States
(12) Patent Application Publication
(10) Pub. No.: US 2026/0150766 A1
(43) Pub. Date: May 28, 2026

(54) DIRECT BONDED METAL (DBM) AND CONNECTION TECHNOLOGY

(71) Applicant: SEMICONDUCTOR COMPONENTS INDUSTRIES, LLC, Scottsdale, AZ (US)

(72) Inventors: Peng HE, Suzhou (CN); JianFeng WANG, Suzhou (CN); XiaoMin SHI, Suzhou (CN); AnAn XING, Suzhou (CN); XinCheng JIN, Suzhou (CN)

(73) Assignee: SEMICONDUCTOR COMPONENTS INDUSTRIES, LLC, Scottsdale, AZ (US)

(21) Appl. No.: 18/957,237

(22) Filed: Nov. 22, 2024

(51) Int. Cl. H01L 23/498; H01L 21/48

(52) U.S. Cl. CPC H10W 90/701; H10W 70/041; H10W 70/479; H10W 70/048

(57) ABSTRACT

Described implementations provide an apparatus that includes a direct bonded metal (DBM) substrate including at least a metal layer coupled to a dielectric layer, a semiconductor device coupled to the DBM substrate, a first protrusion associated with the metal layer, and a conductive portion of a package including a second protrusion that is configured to engage with the first protrusion.

### TECHNICAL FIELD

This description relates to semiconductor packaging techniques for power modules.

### BACKGROUND

Semiconductor devices have been developed for use in various applications associated with power supply and power management. For example, power modules may use a combination of a transistor and a diode, such as an Insulated Gate Bipolar Transistor (IGBT) and a Fast Recovery Diode (FRD). Power modules may also include integrated circuits (ICs). Semiconductor devices packaged within a power module may have high demands in terms of electrical, mechanical, and thermal reliability.

Integrated circuit packaging is the final stage of semiconductor device fabrication, in which the semiconductor die, or dies are encapsulated in a package that prevents physical damage and corrosion. The package supports the electrical contacts which connect the semiconductor devices to a circuit board. An integrated circuit package or semiconductor device package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The semiconductor device package provides a means for connecting the semiconductor devices or integrated circuits to the external environment, such as a printed circuit board, via leads such as lands, balls, or pins and provides a means for protection against threats such as mechanical impact, chemical contamination, and/or light exposure. An example package may include multiple semiconductor die mounted on a substrate. With an increasing demand for high-performance integrated circuits, new improvements are needed in packaging technologies to improve the performance and reliability of integrated circuits.

### SUMMARY

According to one general aspect, an apparatus includes a direct bonded metal (DBM) substrate including at least a metal layer coupled to a dielectric layer, a semiconductor device coupled to the DBM substrate, a first protrusion associated with the metal layer, and a conductive portion of a package including a second protrusion that is configured to engage with the first protrusion.

According to one general aspect, an apparatus includes a direct bonded metal (DBM) substrate including at least a metal layer coupled to a dielectric layer, wherein the DBM substrate includes a plurality of corners, a semiconductor device coupled to the DBM substrate, a plurality of first protrusions associated with the metal layer, wherein at least one of the plurality of first protrusions is disposed in proximity to a respective corner of the plurality of corners of the DBM substrate, and a conductive portion of a package including a plurality of second protrusions, wherein at least one of the plurality of the second protrusions is configured to engage with a respective one of the first protrusions to position the conductive portion of the package with respect to the DBM substrate.

According to another general aspect, a method includes forming a first protrusion associated with a metal layer of a direct bonded metal (DBM) substrate, the DBM substrate including at least the metal layer coupled to a dielectric layer, coupling a semiconductor device to the DBM substrate, and mechanically engaging the first protrusion with a second protrusion of a conductive portion of a package.

The details of one or more implementations are set forth in the accompanying drawings and the description below. Other features will be apparent from the description and drawings, and from the claims.

### BRIEF DESCRIPTION OF THE DRAWINGS

FIG. 1A is a cross-sectional view of a semiconductor device package.

FIG. 1B shows an example semiconductor device package including various semiconductor die mounted on a DBM substrate.

FIG. 2 illustrates a top perspective view of the example direct bonded metal (DBM) substrate of FIGS. 1A-1B.

FIG. 3A shows an example semiconductor device package including various semiconductor die mounted on a DBM substrate.

FIG. 3B illustrates a cross-sectional view of the semiconductor device package 100 of FIG. 3A and FIG. 1.

FIG. 3C also illustrates a detailed partial view 306 of cross-section 300 from direction 313.

FIG. 4A shows an example semiconductor device package including various semiconductor die mounted on a DBM substrate.

FIG. 4B illustrates a cross-sectional view of the semiconductor device package of FIG. 4A and FIG. 1.

FIG. 4C illustrates a detailed partial view of cross-section from direction.

FIG. 4D illustrates a detailed partial view of cross-section from direction, which shows a second positioning protrusion.

FIG. 5 is a flow chart illustrating a method of making a semiconductor device package.

### DETAILED DESCRIPTION

Semiconductor device packages (e.g., semiconductor device modules) should provide high levels of electrical, mechanical, and thermal reliability, in a cost-efficient and space-efficient manner.

Semiconductor device modules can include a direct-bonded metal (DBM) substrate, such as, for example, a direct-bonded copper (DBC) substrate. In some implementations, DBC substrates may be used in some power modules, because of their very good thermal conductivity. In some implementations, a DBC substrate is composed of (or may include) a ceramic oxide substrate (baseplate) (which may be referred to herein as a dielectric layer or ceramic material layer) with a layer of copper coupled to one or both sides by, for example, a high-temperature oxidation process.

As noted, a DBM or DBC substrate may include a dielectric layer (e.g., a ceramic material layer) with direct-bonded metal, for example, a patterned metal layer including one or more patterned metal layer portions disposed on at least one side of the ceramic material layer. DBM is used in power device modules, and the DBM is usually connected to a leadframe through soldering. This connection between DBM and leadframe typically includes reflow soldering and/or sintering, which is a high-temperature process. DBM (e.g., DBC) is prone to deformation at high temperatures and generates stress at the connection with the leadframe. The deformation and stress of DBM at the high temperature can make it prone to cracking, leading to device failure. Also, in some cases, it may be challenging to provide accurate positioning between the leadframe and the DBM substrate.

Although referred to, by way of example, as a leadframe throughout this detailed description, the leadframe can include any type of conductive portion of a package (e.g., conductive portion, conductive terminal) that can provide an external connection point from a package. Accordingly, the leadframe can be referred to as a conductive portion of the package.

Accordingly, described implementations provide a semiconductor device package that includes a DBM substrate including at least a metal layer (e.g., a patterned metal layer) coupled to a dielectric (or ceramic material) layer. The semiconductor device package includes a first protrusion (e.g., a positioning protrusion) associated with (e.g., coupled to or formed as part of) the metal layer, and a leadframe including a second protrusion (e.g., a leadframe protrusion) that is configured to engage with the first protrusion. Thus, the first protrusion is configured to engage with the second protrusion. In an example, the leadframe may be coupled (e.g., welded, soldered or sintered) to the first protrusion, and/or the first protrusion may be coupled (e.g., welded) to the second protrusion. In an example, the first protrusion and the second protrusion may be configured to mechanically engage with each other to stabilize and/or position the leadframe with respect to the DBM substrate. For example, the first and second protrusions may be configured to allow the second protrusion to be inserted into or disposed within an opening of the first protrusion.

In this manner, an improved semiconductor device package is provided in which there is reduced stress and cracking, e.g., via engagement of the first and second protrusions and/or use of welding instead of soldering of this connection between leadframe and DBM. Also, this improved semiconductor device package provides more reliable and/or accurate positioning between the leadframe and the DBM, and improved stability, based on the engagement of the first and second protrusions. For example, a positioning offset or error in the positioning or placement of the leadframe with respect to the DBM may be avoided or at least reduced based on the engagement between the first and second protrusions, such as an insertion of the second protrusion into the first protrusion, to more accurately position the leadframe with respect to the DBM.

In some implementations, the first protrusion (e.g., positioning protrusion) may include an opening therein, and the second protrusion (e.g., leadframe protrusion, or leadframe pin) may disposed within or inserted into the opening of the first protrusion to form a mechanical engagement or interconnection between the first protrusion and the second protrusion to stabilize and position the leadframe with respect to the DBM substrate. In an example, the first protrusion may include a positioning protrusion that is coupled to or formed as part of the metal layer, and the second protrusion may include a leadframe protrusion that is formed as part of the leadframe. For example, the first protrusion (e.g., positioning protrusion) may be patterned as part of the metal layer, or the first protrusion may be welded or soldered to the metal layer. In an example, an upper surface of the first protrusion may be welded to an opposing lower surface of the leadframe, e.g., wherein the first and second protrusions are mechanically engaged. For example, a welding may be provided or performed between the leadframe or leadframe protrusion and the positioning protrusion, e.g., after the leadframe protrusion is inserted into or disposed within the opening of the positioning protrusion.

In some implementations, the first protrusion (e.g., positioning protrusion) may include a cylindrical portion (e.g., sleeve or bushing) having a round or cylindrical opening therein (e.g., having a cylindrical or round cross-sectional shape). For example, in some implementations, the first protrusion may include a tubular sleeve having (from a cross-sectional perspective) a tubular or rectangular opening therein. In other implementations, the first protrusion (e.g., positioning protrusion) may have a different shape, e.g., have a different cross-sectional shape. The second protrusion (e.g., leadframe protrusion) may also have various shapes (from a cross-sectional perspective), e.g., such as a round or cylindrical shape, a rectangular or tubular shape, or other shape.

In some implementations, the DBM substrate may include a plurality of corners, e.g., four corners, and the first protrusion may be disposed (or located or positioned) in proximity (e.g., nearby or adjacent) to a corner of the DBM substrate.

In some implementations, there may be a plurality of first protrusions (e.g., a plurality of positioning protrusions) associated with the metal layer (e.g., coupled to the metal layer, or formed as part of the metal layer), and a plurality of second protrusions (e.g., a plurality of leadframe protrusions, or leadframe pins), wherein one or more first protrusions may be configured to engage with a respective second protrusion. In an example, one or more of the plurality of first protrusions (e.g., positioning protrusions) may be disposed in proximity to (e.g., located or positioned at or near) a respective corner of the plurality of corners of the DBM substrate.

An integrated circuit (IC) package (e.g., a semiconductor device package) may include at least one semiconductor die mounted on a leadframe structure that includes leads providing external electrical connections (external to the package) for individual devices or integrated circuits in the semiconductor die. The semiconductor die can be mounted on a paddle or flag in the leadframe structure using a solder or a conductive adhesive. Wire bonds and/or clips may be used to electrically connect various circuits or devices, or electrically connect an IC or circuit to a leadframe lead, or provide other electrical connection. A wire bond may form a loop (e.g., a vertical loop) that extends from a contact pad on the first semiconductor die to a contact pad on the second semiconductor die or to a post in a leadframe. Further, device contact pads on the semiconductor die may be electrically connected using, for example, wire bonds (e.g., aluminum or copper wire bonds) to respective ones of the leads. The leadframe leads (which may be referred to as leads), which extend to outside of the package body, form external terminal pins that can be used to mount the package on a printed circuit board (PCB) or terminal strip. In some implementations, the terminal pins can be installed in sockets or soldered to a PCB or terminal strip.

For various applications (such as for power applications), the semiconductor device package may include various devices, ICs and/or circuits, e.g., such as silicon devices, silicon carbide transistors, gallium nitride devices, insulated gate bipolar transistor (IGBT), fast recovery diode (FRD), negative temperature coefficient (NTC) thermistors, integrated circuits (ICs), or other devices or circuits.

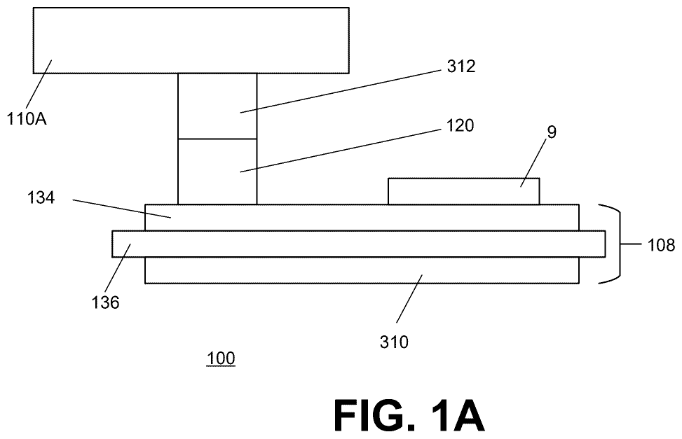

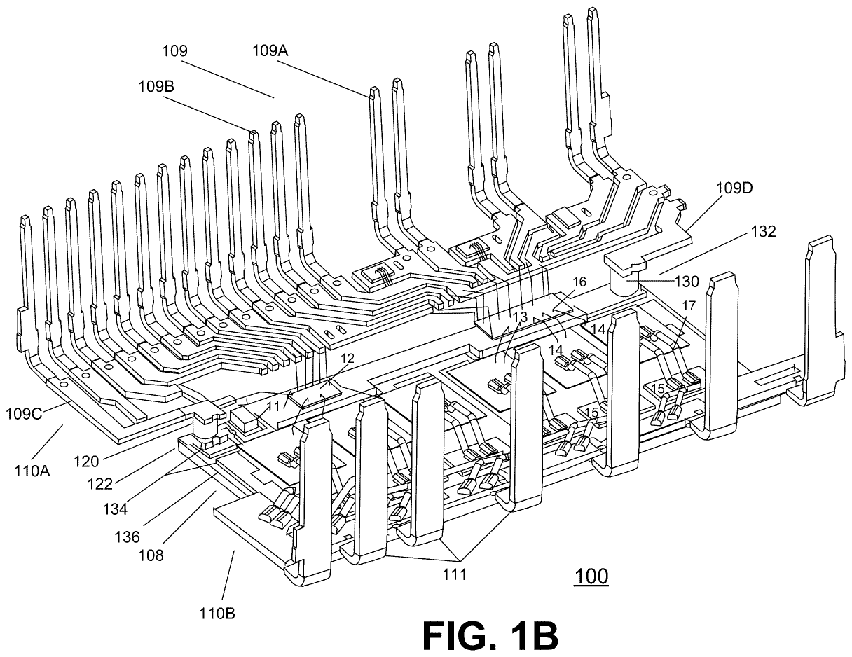

FIG. 1A is a cross-sectional view of a semiconductor device package. As shown in FIG. 1A, the semiconductor device package 100 includes a DBM substrate 108 including at least patterned metal layer 134 (which may include one or more patterned metal layer portions) coupled to a dielectric (or ceramic material) layer 136. DBM substrate 108 may also include a lower (or second) metal layer 310 that is coupled to a lower side of dielectric layer 136. Patterned metal layer 134 and lower (or second) metal layer 310 may be copper or copper alloy, or other metal.

One or more semiconductor die, such as semiconductor die 9, may be mounted on DBM substrate 108. A positioning protrusion 120 is associated with the patterned metal layer 134 of DBM substrate 108, e.g., the positioning protrusion 120 may be formed as part of the patterned metal layer 134, or the positioning protrusions 120 may be coupled to the patterned metal layer 134 such as via welding, soldering, sintering or other technique.

Leadframe 110A may include a leadframe protrusion 312, which may be formed as part of leadframe 110A, e.g., where the leadframe 110A and leadframe protrusion 312 may be formed as one integral piece, e.g., via stamping and/or etching, and then bending as necessary to provide the required shape. In an example, the positioning protrusion 120 and the leadframe protrusion 312 may be configured to engage (e.g., mechanically engage) with each other to stabilize and/or position leadframe 110A with respect to DBM substrate 108. For example, the positioning protrusion 120 and leadframe protrusion 312 may be configured to allow the leadframe protrusion 312 to be inserted into or disposed within an opening of the positioning protrusion 120. In this manner, an improved semiconductor device package is provided in which there is reduced stress and cracking, provides a more reliable and/or more accurate positioning between the leadframe 110A and the DBM substrate 108, and/or provides improved stability, e.g., based on the engagement of the leadframe protrusion 312 with the positioning protrusion 120.

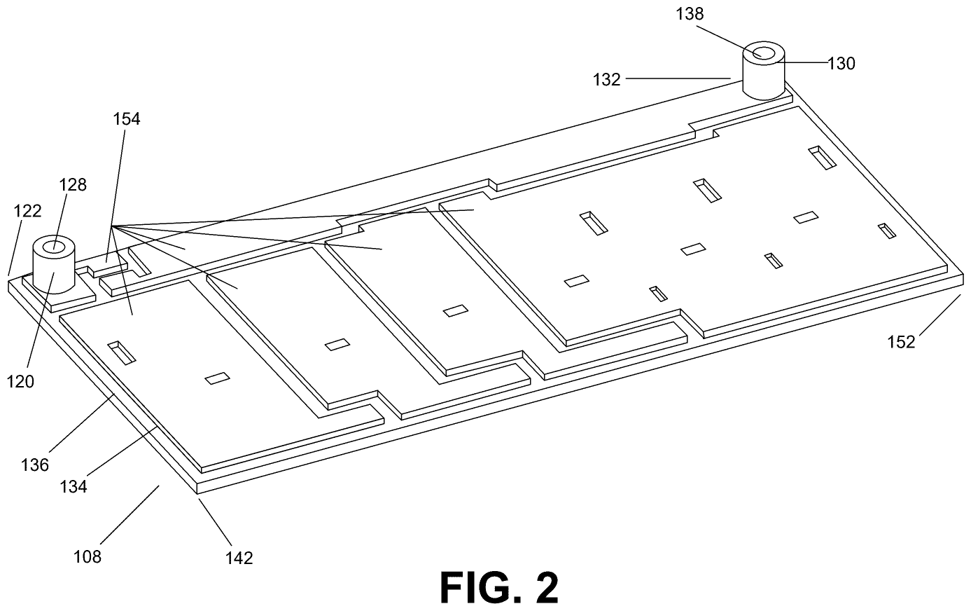

FIG. 1B shows an example semiconductor device (or IC) package including various semiconductor die mounted on a DBM substrate 108. FIG. 2 illustrates a top perspective view of the example direct bonded metal (DBM) substrate 108 of FIG. 1.

The DBM substrate 108 may include at least a patterned metal layer 134 coupled to (or disposed on) a dielectric (or ceramic material) layer 136. The patterned metal layer 134 may include (or may be patterned to include) one or more patterned metal layer portions 154. The semiconductor die may, for example, include a thermistor 11, a first controller IC chip 12, and a second IC controller chip 13, a first power device die 14 and a second power device die 15. For example, the first power device die 14 may be an IGBT die, and the second power device die 15 may be a FRD die. In example implementations, as shown in FIG. 1, DBM substrate 108 may be coupled to leadframes (e.g., including leadframe 110A and/or leadframe 110B) of semiconductor device package 100. Leadframe 110A may include leadframe leads 109, and leadframe 110B may include leadframe leads 111. Leadframe leads 109 may include leadframe lead 109A, leadframe lead 109B, leadframe lead 109C and leadframe lead 109D, for example. Leadframes 110A and 110B may be coupled together or formed together, or may be one leadframe.

Wire bonds and/or clips are provided, which may provide electrical connections between ICs, circuits, devices, leadframe leads, etc. The example wire bonds in FIG. 1B may include wire bonds 16 that electrically connect second IC chip 115 to the first power device die 114. Additional wire bonds may be provided, e.g., that electrically connect first IC chip 12 to various leads 109 of leadframe 110A, and wire bonds or clips that electrically connect first IC chip 12 to the leadframe leads 109. Wire bonds 17 are also provided that connect first power device die 14 to second power device die 15. In example implementations, some of the wire bonds (e.g., wire bond 17) may include larger diameter wire (e.g., aluminum wire, and that may be larger in diameter than wire bonds 16) that is suitable, for example, for carrying electrical power. These are merely examples, and other wire bonds, or clips, may be used or provided.

Also, semiconductor device package 100 may include one or more positioning protrusions, such as positioning protrusions 120, 130, etc., as shown in FIGS. 1B and 2. In an example, one or more of the positioning protrusions may be or may include, for example a cylindrical sleeve or cylindrical bushing having a round or cylindrical opening therein. For example, in some implementations, one or more of the positioning protrusions may include a tubular sleeve having a tubular or rectangular opening therein, or may have other shape. For example, as shown in FIG. 2, positioning protrusion 120 may include an opening 128, and positioning protrusion 130 may include an opening 138. The positioning protrusions (e.g., 120, 130, . . . ) may be associated with the patterned metal layer 134 of DBM substrate 108, e.g., the positioning protrusions 120, 130 may be formed as part of the patterned metal layer 134, or the positioning protrusions 120, 130 may be coupled to the patterned metal layer 134 such as via ultrasonic welding, laser welding, soldering, sintering or other technique.

In some implementations, the DBM substrate 108 may include a plurality of corners, e.g., such as corners 122, 132, 142 and 152 (e.g., see FIG. 2). In example embodiments, one or more of the positioning protrusions may be disposed (e.g., located or positioned or provided) in proximity (e.g., nearby or adjacent) to (or at) a corner of the DBM substrate 108. For example, positioning protrusions 120 and 130 may be in proximity to corners 122 and 132, respectively, as shown in FIGS. 1B and 2. While only two positioning protrusions (120, 130) are shown in FIG. 1B and FIG. 2, any number of positioning protrusions may be used, e.g., 1, 2, 3, 4, 5 (or more) positioning protrusions. For example, although not shown in either FIG. 1B or 2, positioning protrusion(s) may also be disposed in proximity to one or more of corners 142 and 152 (see FIG. 2).

Although not shown in FIG. 1A, 1B or 2, the semiconductor dies, ICs, devices, DBM substrate 108 and other components of semiconductor device package 100 may be encapsulated in a mold body (such as a mold body made of a plastic or an epoxy) to protect the semiconductor dies, ICs, devices and other components of the semiconductor device package 100 against environmental threats such as mechanical impact, chemical contamination, and/or light exposure.

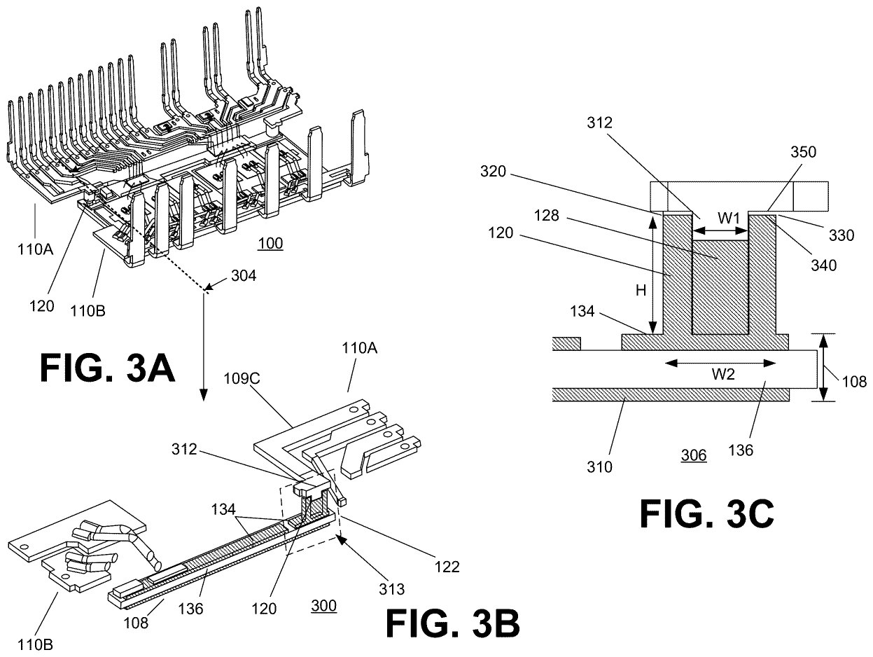

FIG. 3A shows an example semiconductor device package including various semiconductor die mounted on a DBM substrate. FIG. 3B illustrates a cross-sectional view of the semiconductor device package 100 of FIG. 3A and FIG. 1. Referring to FIG. 3B, cross-section 300 of semiconductor device package 100 is based on a cross-section at line 304 of semiconductor device package 100. Cross-section 300 shows leadframes 110A and 110B, including lead 109C. Leadframes 110A and 110B may be coupled together or formed together. Cross-section 300 also shows DBM substrate 108 including at least a patterned metal layer 134 (which may include one or more patterned metal layer portions 154, shown in FIG. 2) coupled to dielectric (or ceramic material) layer 136.

FIG. 3C also illustrates a detailed partial view 306 of cross-section 300 from direction 313. As shown in FIG. 3C, DBM substrate 108 may include patterned metal layer 134 coupled to dielectric (or ceramic material) layer 136. DBM substrate 108 may also include a lower (or second) metal layer 310 that is coupled to a lower side of dielectric layer 136. Patterned metal layer 134 and lower metal layer 310 may be copper or copper alloy, or other metal.

Also, as shown in FIGS. 3B and 3C, positioning protrusion 120 is associated with patterned metal layer 134. In example embodiments, positioning protrusion 120 may be disposed (or provided, located or positioned) on patterned metal layer 134 in proximity to (e.g., adjacent, near or at) a corner 122 of DBM substrate 108. Positioning protrusion 120 may be copper, copper alloy or other metal, and may be made of the same metal as patterned metal layer 134. Positioning protrusion 120 may be, for example, formed as part of metal layer 134, e.g., by being patterned with or as part of the patterned metal layer 134. Or, for example, positioning protrusion 120 may be welded, soldered or sintered to patterned metal layer 134 (or soldered, welded or sintered to at least one of the patterned metal layer portions 154 (FIG. 2) of patterned metal layer 134). Positioning protrusion 120 may be or may include, for example a cylindrical sleeve or cylindrical bushing having a round or cylindrical opening therein (opening 128). Or, positioning protrusion 120 may be or may include a tubular sleeve or bushing having a tubular or rectangular opening therein. Or, positioning protrusion 120 may be a different shape. In example embodiments, positioning protrusion 120 may be hollow or at least partially hollow, thus creating or providing an opening 128 within a top or upper side of positioning protrusion 120, such that positioning protrusion 120 is configured to receive leadframe protrusion 312 into opening 128 (e.g., to allow the positioning protrusion 120 and leadframe protrusion 312 to engage).

Also as shown in FIGS. 3A-3C, leadframe lead 109C may include a leadframe protrusion 312 (or leadframe pin), which may be formed as part of leadframe lead 109C, e.g., where the leadframe lead 109C and leadframe protrusion 312 may be formed as one integral piece, e.g., via stamping and/or etching, and then bending as necessary to provide the required shape. In example embodiments, leadframe lead 109C (and other leads) and leadframe protrusion 312 may be constructed from metal sheet or metal material, e.g., either by stamping or etching. Stamping may be or may include an automated mechanical process that employs die and punch sets to progressively achieve the intended form and shape of the lead and leadframe protrusion 312 through a series of stamping/punching steps. Etching may involve selectively covering a sheet of metal with photoresist in accordance with a pattern of the leadframe leads and leadframe protrusion 312. The sheet metal is then exposed to chemical etchants that remove areas of the metal not covered with the photoresist. The leadframe lead(s) and/or leadframe protrusion(s) may be bent into a desired shape. Alternatively, leadframe protrusion 312 may be soldered, sintered or welded to the leadframe lead 109C.

In example embodiments, the leadframe protrusion 312 and positioning protrusion 120 may be configured (e.g., having a shape and/or size) to engage (e.g., mechanically engage) with each other. That is, for example, the leadframe protrusion 312 is configured to have a size and/or shape to mechanically engage with positioning protrusion 120, wherein the leadframe protrusion 312 is (or is at least partially) disposed within or inserted within opening 128 of positioning protrusion 120. That is, as an example of the leadframe protrusion 312 and positioning protrusion 120 configured to engage, the outer size and shape of leadframe protrusion 312 is configured (e.g., via the leadframe manufacturing process, e.g., via stamping etching, or other manufacturing process) to engage or be inserted into or disposed within opening 128 of positioning protrusion 120. That is, for example, the size and shape of the leadframe protrusion 312 is configured to mechanically engage with or be inserted (at least partially) into opening 128 of positioning protrusion 120, and thus provide a mechanical engagement or interconnection between the positioning protrusion 120 and leadframe protrusion 312, e.g., to position or assist in positioning and also improve stability of the leadframe(s) 110A and/or 110B with respect to the DBM substrate 108.

In example embodiments, in order to engage (e.g., mechanically engage or interconnect) the leadframe protrusion 312 with the positioning protrusion 120, the leadframe protrusion 312 may be aligned with (e.g., aligned over) the opening 128 of positioning protrusion 120, and the lead 109C is pressed or pushed downward to insert the leadframe protrusion 312 (of lead 109C) into opening 128 of positioning protrusion 120. In this manner the leadframe protrusion 312 may be engaged with the positioning protrusion 120, e.g., in order to stabilize the connection between the leadframe 110A and the DBM substrate 108, and also to improve positioning accuracy between the leadframe 110A and DBM substrate 108.

Also, as shown in FIGS. 3B-3C, after the leadframe protrusion 312 is engaged with positioning protrusion 120, welding (e.g., laser welding and/or ultrasonic welding) may be performed between the leadframe lead 109C (and/or leadframe protrusion 312) and the positioning protrusion 120 to secure the connection between the leadframe 110A and the DBM substrate 108. Welding may be performed in different areas. For example, the leadframe lead 109C and/or the leadframe protrusion 312 may be welded to the positioning protrusion 120. For example, as shown in FIG. 3C, welding may be applied to areas 320 and 330 to provide a welding connection between leadframe 109C (or leadframe protrusion 312) and positioning protrusion 120. In example embodiments, after the leadframe protrusion 312 and positioning protrusion 120 are engaged, welding may be performed to secure the positioning protrusion 120 to leadframe or leadframe protrusion. For example, an upper surface 340 of positioning protrusion 120 may be welded to an opposing lower surface 350 of leadframe 109C or a surface(s) of leadframe protrusion 312, e.g., to secure the positioning protrusion 120 to the leadframe or leadframe protrusion 312. For example, welding may applied between positioning protrusion 120 and either a lower surface 350 of leadframe or leadframe protrusion 312, in one or more spots or locations, or all the way around positioning protrusion 120.

A connection between DBM and leadframe typically requires reflow soldering, which is a high-temperature process. DBM is prone to deformation at high temperatures and generates stress at the connection with the leadframe, which can lead to cracking and device failure. Also, positioning misalignments can occur between the leadframe and the DBM substrate. However, in example embodiments described herein, a positioning protrusion 120 and a leadframe protrusion 312 are configured to engage (e.g., mechanically engage or interconnect with each other, such as via insertion of the leadframe protrusion 312 into the opening 128 of positioning protrusion 120). According to example embodiments, this structure and engagement of these two protrusions offers several advantages: 1) due to engagement between the leadframe protrusion 312 and positioning protrusion 120 (e.g., insertion of leadframe protrusion 312 into opening of positioning protrusion 120), the positioning accuracy of the leadframes 110A and/or 110B with respect to the DBM substrate 108 is improved; 2) the engagement or interconnection (e.g., mechanical engagement and/or physical interconnection) between the leadframe protrusion 312 and positioning protrusion 120 provides improved stability of the connection between the leadframes 110A and/or 110B and the DBM substrate 108 (e.g., which may allow welding to be performed instead of soldering between the leadframe lead 109C or leadframe protrusion 312 and positioning protrusion 120); and 3) welding, for example, rather than soldering or sintering, may be used to connect or couple the leadframe lead 109C and/or leadframe protrusion 312 to the positioning protrusion 120, which should reduce the amount of device cracking and failures, as compared to soldering.

With respect to the examples shown in FIGS. 3A through 3C, a height H of positioning protrusion 120 may be greater than a width W1 of positioning protrusion 120. Alternatively, a height H of positioning protrusion 120 may be less than a width W1 of positioning protrusion 120. A diameter or width W2 of the opening 128 of positioning protrusion 120 may be less than a height H of the positioning protrusion 120. Alternatively, a diameter or width W2 of the opening 128 of positioning protrusion 120 may be greater than a height H of the positioning protrusion 120. Also, an inner width (e.g., diameter) of opening 128 may be greater than (e.g., slightly greater than) an outer width (e.g., outer diameter) of leadframe protrusion 312, so that leadframe protrusion 312 may be inserted within opening 128 of positioning protrusion 120.

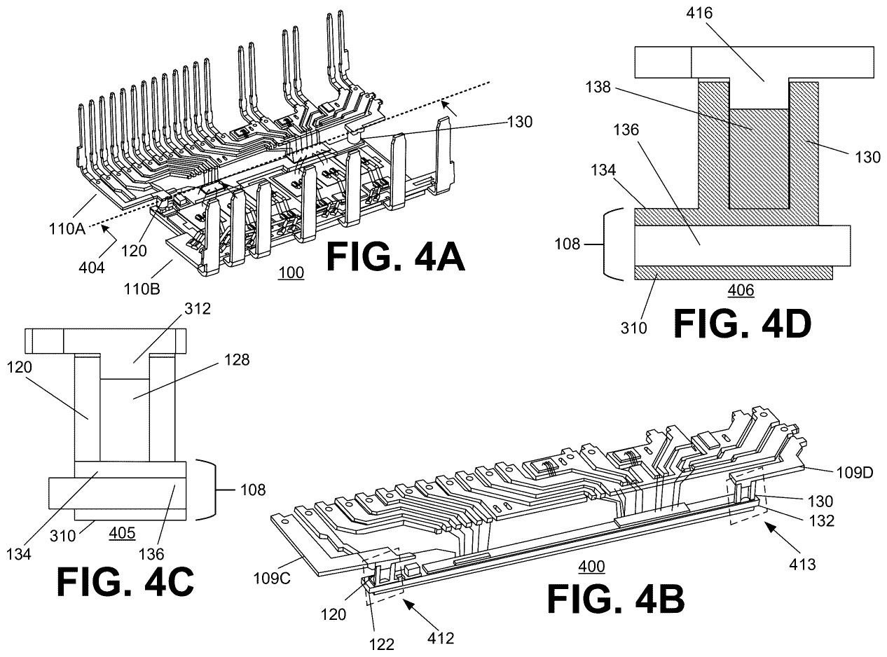

FIG. 4A shows an example semiconductor device package including various semiconductor die mounted on a DBM substrate. The semiconductor device package 100 shown in FIG. 4A includes leadframes 109A and 110A, and positioning protrusions 120 and 130. FIG. 4B illustrates a cross-sectional view of the semiconductor device package 100 of FIG. 4A and FIG. 1. Cross-section 400 (FIG. 4B) of semiconductor device package 100 is based on a cross-section at line 404 of semiconductor device package 100 (shown in FIG. 4A). FIG. 4C illustrates a detailed partial view 405 of cross-section 400 from direction 412. As shown in FIG. 4C, DBM substrate 108 may include patterned metal layer 134 coupled to dielectric (or ceramic material) layer 136. DBM substrate 108 may also include a lower (or second) metal layer 310 that is coupled to a lower side of dielectric layer 136. Also, as shown in FIG. 4C, positioning protrusion 120 is associated with patterned metal layer 134. In example embodiments, positioning protrusion 120 may be disposed (or provided, located or positioned) on patterned metal layer 134 in proximity to (e.g., adjacent, near or at) a corner 122 of DBM substrate 108. In example embodiments, positioning protrusion 120 may be hollow or at least partially hollow, thus creating or providing an opening 128 within a top or upper side of positioning protrusion 120, such that positioning protrusion 120 is configured to receive leadframe protrusion 312 into opening 128 (e.g., to allow the positioning protrusion 120 and leadframe protrusion 312 to engage). The positioning protrusion 120 and leadframe protrusion 312 are described in greater detail with respect to FIGS. 3B and 3C, and will not be repeated here.

FIG. 4D illustrates a detailed partial view 406 of cross-section 400 from direction 413, which shows a second positioning protrusion (130). As shown in cross-section 400 and detailed partial view 406, DBM substrate 108 may include at least patterned metal layer 134 coupled to dielectric (or ceramic material) layer 136. DBM substrate 108 may also include a lower (or second) metal layer 310 that is coupled to a lower side of dielectric layer 136. Patterned metal layer 134 and lower metal layer 310 may be copper or copper alloy, or other metal. At layer 134, the patterned metal layer portions of metal layer 134 may be the same metal layer portion or different metal layer portions for detailed partial views 306 and 406.

Also, as shown in FIGS. 4B and 4D, positioning protrusion 130 is associated with patterned metal layer 134. In example embodiments, positioning protrusion 130 may be disposed (or provided, located or positioned) on patterned metal layer 134 in proximity to (e.g., adjacent, near or at) a corner 132 of DBM substrate 108. Positioning protrusion 130 may be copper, copper alloy or other metal, and may be made of the same metal as patterned metal layer 134. Positioning protrusion 130 may be, for example, formed as part of metal layer 134, e.g., by being patterned with or as part of the patterned metal layer 134. Or, for example, positioning protrusion 130 may be welded or soldered to patterned metal layer 134 (or soldered or welded to at least one of the patterned metal layer portions 154 (FIG. 2) of patterned metal layer 134. Positioning protrusion 130 may be or may include, for example a cylindrical sleeve or cylindrical bushing having a round or cylindrical opening therein (opening 138). Or, positioning protrusion 130 may be or may include a tubular sleeve or bushing having a tubular or rectangular opening therein. Or, positioning protrusion 130 may be a different shape. In example embodiments, positioning protrusion 130 may be hollow or at least partially hollow, thus creating or providing an opening 138 within a top or upper side of positioning protrusion 130. Positioning protrusions 120 and 130 may be the same size and shape, or may be of different sizes and/or shapes.

Also as shown in FIGS. 4B and 4D, leadframe lead 109D may include a leadframe protrusion 416, which may be formed as part of leadframe lead 109D, e.g., where the leadframe lead 109D and leadframe protrusion 416 may be formed as one integral piece, e.g., via stamping and /r etching, and then bending as necessary to provide the required shape. Alternatively, leadframe protrusion 416 may be soldered or welded to the leadframe lead 109D.

In example embodiments, the leadframe protrusion 416 and positioning protrusion 130 may be configured (e.g., having a shape and/or size) to engage (e.g., mechanically engage). That is, for example, the leadframe protrusion 416 is configured to have a size and/or shape to mechanically engage with positioning protrusion 130, wherein the leadframe protrusion 416 is (or is at least partially, or may be) disposed within or inserted within opening 138 of positioning protrusion 130. That is, as an example of the leadframe protrusion 416 and positioning protrusion 130 configured to engage, the outer size and shape of leadframe protrusion 416 is configured (e.g., via the leadframe manufacturing process, e.g., via stamping etching, or other manufacturing process) to engage or be inserted into or disposed within opening 138 of positioning protrusion 130. That is, for example, the size and shape of the leadframe protrusion 416 is configured to mechanically engage with or be inserted (at least partially) into opening 138 of positioning protrusion 130, and thus provide a mechanical engagement or interconnection between the positioning protrusion 130 and leadframe protrusion 416, e.g., to position or assist in positioning the leadframes 110A and/or 110B with respect to the DBM substrate 108.

In example embodiments, in order to engage (e.g., mechanically engage or interconnect) the leadframe protrusion 416 with the positioning protrusion 130, the leadframe protrusion 416 may be aligned with (e.g., aligned over) the opening 138 of positioning protrusion 130, and the lead 109D may be pressed or pushed downward to insert the leadframe protrusion 416 (of lead 109D) into opening 138 of positioning protrusion 130. In this manner the leadframe protrusion 416 may be engaged with the positioning protrusion 130, e.g., in order to stabilize the connection between the leadframes 110A and/or 110B and the DBM substrate 108, and also to improve positioning accuracy between the leadframes 110A and/or 110B and DBM substrate 108.

Also, the engagement of protrusions 120 and 312, and also engagement of protrusions 130 and 416, may be performed during assembly. For example, leadframe protrusions 312 and 416 may be aligned with openings 128 and 138 (of positioning protrusions 120, 130), respectively, and then the leadframe protrusions 312 and 416 may be inserted into the openings 128 and 138, to form two (or multiple) protrusion mechanical engagements or interconnections between the leadframe(s) and DBM substrate 108. While only two sets of protrusions are shown (120/312, and 130/416), any number may be used. Welding may be performed between leadframe 109D or leadframe protrusion 416 and positioning protrusion 130 in a same or similar manner(s) as that performed and/or described herein for welding of leadframe 109C or leadframe protrusion 312 with 416 protrusion 120.

The use of multiple (e.g., two, three, four, . . . ) sets of protrusions, with each set of protrusions configured to engage or provide an interconnection, may provide both increased stability and increased alignment between the leadframe(s) and DBM substrate 108, as compared to using only one set (or pair) of protrusions that are configured to engage.

In some implementations, DBM substrate 108 may be composed of (or may include) a ceramic oxide substrate (baseplate) (which may be referred to as a dielectric layer or ceramic material layer) with a layer of copper coupled to one or both sides by, for example, a high-temperature oxidation process. For example, in the high-temperature oxidation process, the copper and baseplate (or dielectric) layers may be heated to a carefully controlled temperature in an atmosphere of nitrogen containing about 30 ppm of oxygen; under these conditions, a copper-oxygen eutectic forms which bonds successfully both to copper and the ceramic oxide baseplate. In some implementations, the top copper layer may be patterned (such as patterned metal layer 134), or can be pre-formed prior to firing or chemically etched using printed circuit board technology to form traces of an electrical circuit, while the lower or bottom copper layer (e.g., lower or second metal layer 310) layer can be maintained as a solid layer. In some implementations, the bottom copper layer (e.g., lower or second metal layer 310) may function as, for example, a heat sink.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature

In some implementations, a leadframe protrusion 312 may be coupled to a leadframe, and/or a positioning protrusion 120 may be coupled to a DBM substrate 108 or to a patterned metal layer 134 by using materials such as, for example, a solder, a sintering (e.g., silver sintering, copper sintering) material, and/or other metal-to-metal type bonding materials. Alternatively, a leadframe protrusion 312 may be coupled to a leadframe, and/or a positioning protrusion 120 may be coupled to a DBM substrate 108 or to a patterned metal layer 134, by using, for example, a solder process, a sintering process (e.g., a silver sintering process, copper sintering process), and/or other metal-to-metal type bonding processes. In some implementations, sintering can be or can include a process of fusing particles together into one solid mass by using, for example, a combination of pressure and/or heat without melting the materials. Also, a leadframe or a leadframe protrusion 312, for example, may be welded or sintered to a positioning protrusion 120.

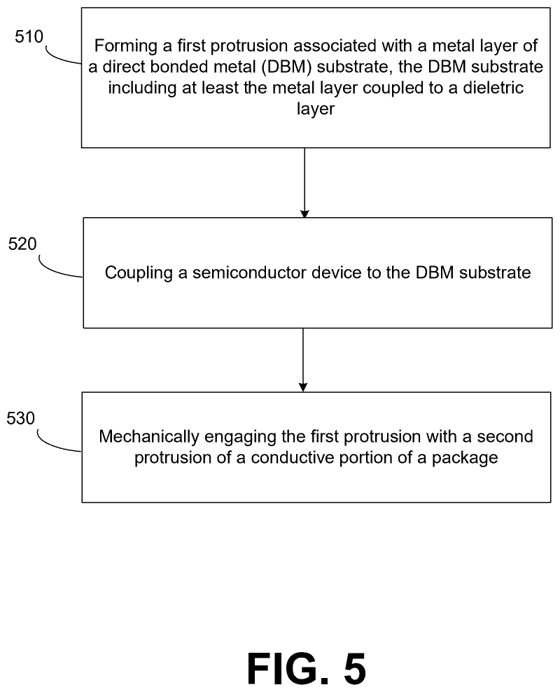

FIG. 5 is a flow chart illustrating a method of making a semiconductor device package. Operation 510 includes forming a first protrusion associated with a metal layer of a direct bonded metal (DBM) substrate, the DBM substrate including at least the metal layer coupled to a dielectric layer. Operation 520 includes coupling a semiconductor device to the DBM substrate. Operation 530 includes mechanically engaging the first protrusion with a second protrusion of a leadframe (e.g., conductive portion of a package).

In example implementations, with respect to the method of FIG. 5, a DBM substrate 108 may be formed or provided, which may include at least patterned metal layer 134 (which may include one or more patterned metal layer portions, that are patterned from metal layer 134) coupled to a dielectric (or ceramic material) layer 136 (FIG. 1A). DBM substrate 108 may also include a lower (or second) metal layer 310 that is coupled to a lower side of dielectric layer 136. Patterned metal layer 134 and lower metal layer 310 may be copper or copper alloy, or other metal. See, e.g., FIGS. 1A, 1B, 2 and 3A-3C.

A positioning protrusion 120 (e.g., see FIGS. 1A, 1B, 2 and 3A-3C) is associated with the patterned metal layer 134 of DBM substrate 108, e.g., the positioning protrusion 120 may be formed as part of the patterned metal layer 134, or the positioning protrusions 120 may be coupled to the patterned metal layer 134 such as via welding, soldering, sintering or other technique. Leadframe 110A may include a leadframe protrusion 312, which may be formed as part of leadframe 110A, e.g., where the leadframe 110A and leadframe protrusion 312 may be formed as one integral piece, e.g., via stamping and/or etching, and then bending as necessary to provide the required shape. In an example, the positioning protrusion 120 and the leadframe protrusion 312 may be configured to engage (e.g., mechanically engage) with each other to position and/or stabilize and/or position leadframe 110A with respect to DBM substrate 108. For example, the positioning protrusion 120 and leadframe protrusion 312 may be configured to allow the leadframe protrusion 312 to be inserted into or disposed within an opening of the positioning protrusion 120. In this manner, an improved semiconductor device package is provided in which there is reduced stress and cracking, provides a more reliable and/or more accurate positioning between the leadframe 110A and the DBM substrate 108, and/or provides improved stability, e.g., based on the engagement of the leadframe protrusion 312 with the positioning protrusion 120.

For example, as shown in FIG. 2, positioning protrusion 120 may include, or may be configured or formed to include, an opening 128. The positioning protrusions 120 may be associated with the patterned metal layer 134 of DBM substrate 108, e.g., the positioning protrusion 120 may be formed as part of the patterned metal layer 134, or the positioning protrusion 120 may be coupled to the patterned metal layer 134 such as via ultrasonic welding, laser welding, soldering, sintering or other technique.

Also, one or more semiconductor die may be mounted on DBM substrate 108. For example, one or more die may be coupled to patterned metal layer 134, e.g., via soldering, welding, sintering or other technique. Wire bonds or clips may provide electrical connections between die and leadframe leads. Also, the semiconductor dies, ICs, devices, DBM substrate 108 and other components of semiconductor device package 100 may be encapsulated in a mold body (such as a mold body made of a plastic or an epoxy) to protect the semiconductor dies, ICs, devices and other components of the semiconductor device package 100 against environmental threats such as mechanical impact, chemical contamination, and/or light exposure.

Positioning protrusion 120 may be welded, soldered or sintered to patterned metal layer 134 (or soldered, welded or sintered to at least one of the patterned metal layer portions 154 (FIG. 2) of patterned metal layer 134). Positioning protrusion 120 may be or may include, for example a cylindrical sleeve or cylindrical bushing having a round or cylindrical opening therein (opening 128). Or, positioning protrusion 120 may be or may include a tubular sleeve or bushing having a tubular or rectangular opening therein. Or, positioning protrusion 120 may be a different shape. In example embodiments, positioning protrusion 120 may be hollow or at least partially hollow, thus creating or providing an opening 128 within a top or upper side of positioning protrusion 120, such that positioning protrusion 120 is configured to receive leadframe protrusion 312 into opening 128 (e.g., to allow the positioning protrusion 120 and leadframe protrusion 312 to engage). Also, a leadframe lead 109C and leadframe protrusion 312 (FIGS. 3B, 3C) may be formed as one integral piece, e.g., via stamping and/or etching, and then bending as necessary to provide the required shape. In example embodiments, leadframe lead 109C (and other leads) and leadframe protrusion 312 may be constructed from metal sheet or metal material, e.g., either by stamping or etching. Stamping may be or may include an automated mechanical process that employs die and punch sets to progressively achieve the intended form and shape of the lead and leadframe protrusion 312 through a series of stamping/punching steps. Etching may involve selectively covering a sheet of metal with photoresist in accordance with a pattern of the leadframe leads and leadframe protrusion 312. The sheet metal is then exposed to chemical etchants that remove areas of the metal not covered with the photoresist. The leadframe lead(s) and/or leadframe protrusion(s) may be bent into a desired shape. Alternatively, leadframe protrusion 312 may be soldered, sintered or welded to the leadframe lead 109C.

In example embodiments, the leadframe protrusion 312 and positioning protrusion 120 may be configured (e.g., having a shape and/or size) to engage (e.g., mechanically engage) with each other. In example embodiments, in order to engage (e.g., mechanically engage or interconnect) the leadframe protrusion 312 with the positioning protrusion 120, the leadframe protrusion 312 may be aligned with (e.g., aligned over) the opening 128 of positioning protrusion 120, and the lead 109C is pressed or pushed downward to insert the leadframe protrusion 312 (of lead 109C) into opening 128 of positioning protrusion 120. In this manner the leadframe protrusion 312 may be engaged with the positioning protrusion 120, e.g., in order to stabilize the connection between the leadframe 110A and the DBM substrate 108, and also to improve positioning accuracy between the leadframe 110A and DBM substrate 108.

Also, as shown in FIGS. 3B-3C, after the leadframe protrusion 312 is engaged with positioning protrusion 120, welding (e.g., laser welding and/or ultrasonic welding), sintering, soldering, or other technique may be performed between the leadframe lead 109C (and/or leadframe protrusion 312) and the positioning protrusion 120 to secure the connection between the leadframe 110A and the DBM substrate 108. Welding may be performed in different areas. For example, the leadframe lead 109C and/or the leadframe protrusion 312 may be welded to the positioning protrusion 120. For example, as shown in FIG. 3C, welding may be applied to areas 320 and 330 to provide a welding connection between leadframe 109C (or leadframe protrusion 312) and positioning protrusion 120. In example embodiments, after the leadframe protrusion 312 and positioning protrusion 120 are engaged, welding may be performed to secure the positioning protrusion 120 to leadframe or leadframe protrusion. For example, an upper surface 340 of positioning protrusion 120 may be welded to an opposing lower surface 350 of leadframe 109C or a surface(s) of leadframe protrusion 312, e.g., to secure the positioning protrusion 120 to the leadframe or leadframe protrusion 312. For example, welding may applied between positioning protrusion 120 and either a lower surface 350of leadframe or leadframe protrusion 312, in one or more spots or locations, or all the way around positioning protrusion 120.

Clause 1. An apparatus, comprising: a direct bonded metal (DBM) substrate including at least a metal layer coupled to a dielectric layer; a semiconductor device coupled to the DBM substrate; a first protrusion associated with the metal layer; and a conductive portion of a package including a second protrusion that is configured to engage with the first protrusion.

Clause 2. The apparatus of clause 1, wherein the conductive portion of the package is welded to the first protrusion.

Clause 3. The apparatus of clause 1, wherein the first protrusion and the second protrusion are configured to mechanically engage with each other to position the conductive portion of the package with respect to the DBM substrate.

Clause 4. The apparatus of clause 1, wherein the first protrusion includes an opening therein, and wherein the second protrusion is disposed within or inserted into the opening of the first protrusion to form a mechanical engagement or interconnection between the first protrusion and the second protrusion.

Clause 5. The apparatus of clause 1, wherein the second protrusion is disposed within an opening of the first protrusion to form a mechanical engagement or interconnection between the first protrusion and the second protrusion to position the conductive portion of the package with respect to the DBM substrate.

Clause 6. The apparatus of clause 1: wherein the conductive portion of the package comprises a leadframe; wherein the first protrusion comprises a positioning protrusion that is coupled to or formed as part of the metal layer; wherein the second protrusion comprises a leadframe protrusion that is formed as part of the leadframe; and wherein the first protrusion and the second protrusion, when mechanically engaged with each other, are configured to position the leadframe with respect to the metal layer or DBM substrate.

Clause 7. The apparatus of clause 1, wherein the first protrusion is patterned as part of the metal layer.

Clause 8. The apparatus of clause 1, wherein the first protrusion is welded to the metal layer.

Clause 9. The apparatus of clause 1, wherein the first protrusion is soldered to the metal layer.

Clause 10. The apparatus of clause 1, wherein an upper surface of the first protrusion is welded to an opposing lower surface of the conductive portion of the package, wherein the first protrusion is mechanically engaged with the second protrusion.

Clause 11. The apparatus of clause 1, wherein the first protrusion comprises a cylindrical sleeve having a round or cylindrical opening therein, wherein the first protrusion is welded to the conductive portion of the package.

Clause 12. The apparatus of clause 1, wherein the first protrusion comprises a tubular sleeve having a tubular or rectangular opening therein, wherein the first protrusion is welded to the conductive portion of the package.

Clause 13. The apparatus of clause 1, wherein the first protrusion is disposed in proximity to a corner of the DBM substrate.

Clause 14. The apparatus of clause 1: wherein the first protrusion comprises a plurality of first protrusions; wherein the second protrusion comprises a plurality of second protrusions; and wherein a respective first protrusion of at least one of the plurality of first protrusions is configured to engage with a respective second protrusion of the plurality of second protrusions to position the conductive portion of the package with respect to the DBM substrate.

Clause 15. A method, comprising: forming a first protrusion associated with a metal layer of a direct bonded metal (DBM) substrate, the DBM substrate including at least the metal layer coupled to a dielectric layer; coupling a semiconductor device to the DBM substrate; and mechanically engaging the first protrusion with a second protrusion of a conductive portion of a package.

Clause 16. The method of clause 15: wherein the first protrusion includes an opening therein; and wherein the mechanically engaging comprises inserting the second protrusion at least partially into the opening of the first protrusion.

Clause 17. The method of clause 15, further comprising performing at least one of: forming the conductive portion of the package to include the second protrusion, wherein the conductive portion of the package including the second protrusion is of unitary or monolithic construction; stamping the conductive portion of the package to include the second protrusion; or etching the conductive portion of the package to include the second protrusion.

Clause 18. The method of clause 15, further comprising performing at least one of: welding the conductive portion of the package to the second protrusion; welding the first protrusion to the second protrusion; or welding an upper surface of the second protrusion to an opposing lower surface of the conductive portion of the package.

Clause 19. The method of clause 15, wherein the forming the first protrusion associated with the metal layer comprises performing at least one of: patterning the metal layer to form the first protrusion to be integral with the metal layer; welding the first protrusion to the metal layer; or soldering the first protrusion to the metal layer.

Clause 20. The method of clause 15, wherein the mechanically engaging comprises: inserting the second protrusion at least partially into an opening of the first protrusion so as to form a mechanical interconnection or engagement between the first protrusion and the second protrusion to position the conductive portion of the package with respect to the DBM substrate or metal layer.

Clause 21. The method of clause 15, wherein the mechanically engaging comprises: aligning the second protrusion with an opening of the first protrusion; and inserting the second protrusion at least partially into the opening of the first protrusion so as to form a mechanical interconnection or engagement between the first protrusion and the second protrusion to position the conductive portion of the package with respect to the DBM substrate or metal layer.

Clause 22. An apparatus, comprising: a direct bonded metal (DBM) substrate including at least a metal layer coupled to a dielectric layer, wherein the DBM substrate includes a plurality of corners; a semiconductor device coupled to the DBM substrate; a plurality of first protrusions associated with the metal layer, wherein at least one of the plurality of first protrusions is disposed in proximity to a respective corner of the plurality of corners of the DBM substrate; and a conductive portion of a package including a plurality of second protrusions, wherein at least one of the plurality of the second protrusions is configured to engage with a respective one of the first protrusions to position the conductive portion of the package with respect to the DBM substrate.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes. In some implementations, sintering can be, or can include a process of fusing particles together into one solid mass by using, for example, a combination of pressure and/or heat without melting the materials.

In some implementations, the DBM substrate can include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, the first metal layer and/or the second metal layer can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate. In some implementations, such as in DBC substrate implementations, the first metal layer and/or the second metal layer is a copper layer.

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor dies may be also connected to lead frame posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

In some implementations, a mold material (e.g., molding material or compound, an encapsulation material) can be or can include a non-conducting layer/material.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer)

In some implementations, a module (e.g., a package including a semiconductor device) can be included in another module. The module can be referred to as a package. For example, one or more modules can be one or more sub modules included within another module. In other words, a first module can be included as a sub module within a second module.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a direct bonded metal (DBM) substrate including at least a metal layer coupled to a dielectric layer;
a semiconductor device coupled to the DBM substrate;
a first protrusion associated with the metal layer; and
a conductive portion of a package including a second protrusion that is configured to engage with the first protrusion.

2. The apparatus of claim 1, wherein the conductive portion of the package is welded to the first protrusion.

3. The apparatus of claim 1, wherein the first protrusion and the second protrusion are configured to mechanically engage with each other to position the conductive portion of the package with respect to the DBM substrate.

4. The apparatus of claim 1, wherein the first protrusion includes an opening therein, and wherein the second protrusion is disposed within or inserted into the opening of the first protrusion to form a mechanical engagement or interconnection between the first protrusion and the second protrusion.

5. The apparatus of claim 1, wherein the second protrusion is disposed within an opening of the first protrusion to form a mechanical engagement or interconnection between the first protrusion and the second protrusion to position the conductive portion of the package with respect to the DBM substrate.

6. The apparatus of claim 1, wherein:
the conductive portion of the package comprises a leadframe;
the first protrusion comprises a positioning protrusion that is coupled to or formed as part of the metal layer;
the second protrusion comprises a leadframe protrusion that is formed as part of the leadframe; and
the first protrusion and the second protrusion, when mechanically engaged with each other, are configured to position the leadframe with respect to the metal layer or DBM substrate.

7. The apparatus of claim 1, wherein the first protrusion is patterned as part of the metal layer.

8. The apparatus of claim 1, wherein the first protrusion is welded to the metal layer.

9. The apparatus of claim 1, wherein the first protrusion is soldered to the metal layer.

10. The apparatus of claim 1, wherein an upper surface of the first protrusion is welded to an opposing lower surface of the conductive portion of the package, wherein the first protrusion is mechanically engaged with the second protrusion.

11. The apparatus of claim 1, wherein the first protrusion comprises a cylindrical sleeve having a round or cylindrical opening therein, wherein the first protrusion is welded to the conductive portion of the package.

12. The apparatus of claim 1, wherein the first protrusion comprises a tubular sleeve having a tubular or rectangular opening therein, wherein the first protrusion is welded to the conductive portion of the package.

13. The apparatus of claim 1, wherein the first protrusion is disposed in proximity to a corner of the DBM substrate.

14. The apparatus of claim 1:
wherein the first protrusion comprises a plurality of first protrusions;
wherein the second protrusion comprises a plurality of second protrusions; and
wherein a respective first protrusion of at least one of the plurality of first protrusions is configured to engage with a respective second protrusion of the plurality of second protrusions to position the conductive portion of the package with respect to the DBM substrate.

15. A method, comprising:
forming a first protrusion associated with a metal layer of a direct bonded metal (DBM) substrate, the DBM substrate including at least the metal layer coupled to a dielectric layer;
coupling a semiconductor device to the DBM substrate; and
mechanically engaging the first protrusion with a second protrusion of a conductive portion of a package.

16. The method of claim 15, wherein:
the first protrusion includes an opening therein; and
the mechanically engaging comprises inserting the second protrusion at least partially into the opening of the first protrusion.

17. The method of claim 15, further comprising performing at least one of:
forming the conductive portion of the package to include the second protrusion, wherein the conductive portion of the package including the second protrusion is of unitary or monolithic construction;
stamping the conductive portion of the package to include the second protrusion; or
etching the conductive portion of the package to include the second protrusion.

18. The method of claim 15, further comprising performing at least one of:
welding the conductive portion of the package to the second protrusion;
welding the first protrusion to the second protrusion; or
welding an upper surface of the second protrusion to an opposing lower surface of the conductive portion of the package.

19. The method of claim 15, wherein the forming the first protrusion associated
with the metal layer comprises performing at least one of:
patterning the metal layer to form the first protrusion to be integral with the metal layer;
welding the first protrusion to the metal layer; or
soldering the first protrusion to the metal layer.

20. The method of claim 15, wherein the mechanically engaging comprises:
inserting the second protrusion at least partially into an opening of the first protrusion so as to form a mechanical interconnection or engagement between the first protrusion and the second protrusion to position the conductive portion of the package with respect to the DBM substrate or metal layer.

21. The method of claim 15, wherein the mechanically engaging comprises:
aligning the second protrusion with an opening of the first protrusion; and
inserting the second protrusion at least partially into the opening of the first protrusion so as to form a mechanical interconnection or engagement between the first protrusion and the second protrusion to position the conductive portion of the package with respect to the DBM substrate or metal layer.

22. An apparatus, comprising:
a direct bonded metal (DBM) substrate including at least a metal layer coupled to a dielectric layer, wherein the DBM substrate includes a plurality of corners;
a semiconductor device coupled to the DBM substrate;
a plurality of first protrusions associated with the metal layer, wherein at least one of the plurality of first protrusions is disposed in proximity to a respective corner of the plurality of corners of the DBM substrate; and
a conductive portion of a package including a plurality of second protrusions, wherein at least one of the plurality of the second protrusions is configured to engage with a respective one of the first protrusions to position the conductive portion of the package with respect to the DBM substrate.

23. The apparatus of claim 1, wherein the second protrusion is disposed within an opening of the first protrusion to form a mechanical engagement or interconnection between the first protrusion and the second protrusion to position the conductive portion of the package with respect to the DBM substrate.
